(19) United States
(12) Patent Application Publication
(10) Pub. No.: US 2018/0068875 A1
(43) Pub. Date: Mar. 8, 2018

(54) SUBSTRATE PROCESSING APPARATUS

(71) Applicant: SCREEN Holdings Co., Ltd., Kyoto (JP)

(72) Inventors: Rei TAKEAKI, Kyoto-shi (JP); Koji ANDO, Kyoto-shi (JP); Tadashi MAEGAWA, Kyoto-shi (JP); Yosuke YASUTAKE, Kyoto-shi (JP)

(21) Appl. No.: 15/691,943

(22) Filed: Aug. 31, 2017

(30) Foreign Application Priority Data
Sep. 8, 2016 (JP) 2016-175353

(51) Int. Cl. H01L 21/67; H01L 21/683

(52) U.S. Cl. CPC H01L 21/67023; H01L 21/683

(57) ABSTRACT

A substrate processing apparatus includes: a spin chuck adapted to hold a substrate having a substantially circular outer shape with the principal surface of the substrate set substantially horizontally and rotate the substrate with the center of the substrate as a rotation center; a processing liquid ejection nozzle adapted to eject a processing liquid to the circumferential edge part of the substrate rotated held by the spin chuck; and a cup adapted to be disposed in the external circumferential part of the substrate rotated held by the spin chuck and collect the processing liquid scattered from the substrate, and further includes, above the surface of the substrate rotated held by the spin chuck, an anti-splash member that is disposed between a collision position where the processing liquid scattered from the substrate collides with the cup and the substrate and for preventing the processing liquid having collided with the cup from reaching the surface of the substrate rotated held by the spin chuck.

### BACKGROUND OF THE INVENTION

### 1. Field of the Invention

The present invention relates to a substrate processing apparatus adapted to process the circumferential edge part of a substrate having a substantially circular outer shape, such as a semiconductor wafer.

### 2. Description of the Prior Art

A device pattern to be formed on the surface of such a substrate is formed in an inner area separate from the circumferential edge part of the substrate by a certain distance. On the other hand, in a deposition process for forming the device pattern, deposition is performed over the entire surface area of the substrate. For this reason, a film formed in the circumferential edge area of the substrate is not only unnecessary but reduces substrate processing quality in cases such as when removed from the substrate and attached to the device pattern area in subsequent processing steps. In addition, the film may act as an obstacle to the subsequent processing steps.

For this reason, there have been employed substrate processing apparatuses adapted to supply an etching liquid or the like to the circumferential edge part also referred to as a bevel on the outer side of a device pattern on a substrate, and thereby remove a film formed on the circumferential edge part (see Japanese Unexamined Patent Publications JP-A 2011-066194 and JP-A 2009-070946).

In such substrate processing apparatuses, the substrate is held by a spin chuck and then rotated with the center of the substrate as a rotation center. After that, a processing liquid ejection nozzle is arranged above the circumferential edge part of the substrate, and from the processing liquid ejection nozzle, a processing liquid is continuously supplied to the circumferential edge part of the substrate in rotation. In doing so, the film formed on the circumferential edge part of the substrate is etched and removed.

Since the substrate processing apparatus described in JP-A 2011-066194 or JP-A 2009-070946 is configured to continuously eject the processing liquid to the circumferential edge part of the substrate rotated held by the spin chuck, the processing liquid ejected to the circumferential edge part of the substrate from the processing liquid ejection nozzle is scattered from a supply position on the upper surface of the circumferential edge part of the substrate outward of the substrate along with the rotation of the substrate. Therefore, in the external circumferential part of the substrate rotated held by the spin chuck, a cup for collecting the processing liquid scattered from the substrate is disposed.

Meanwhile, in such a substrate processing apparatus, along with the rotation of the substrate, air flow circulating in the same direction as a rotational direction of the substrate is generated in the cup. As a result, the processing liquid scattered from the substrate and collected by the cup is scattered when colliding with the cup, and part of the processing liquid may reach the surface of the substrate while joining the air flow. If the part of the processing liquid is attached to a device pattern area on the surface of the substrate, there occurs a problem of causing a defect in a device pattern.

### SUMMARY OF THE INVENTION

Therefore, an object of the present invention is to provide a substrate processing apparatus capable of suppressing a processing liquid from reaching a device pattern area on the surface of a substrate and properly processing the circumferential edge part of the substrate.

The above-described object of the present invention is accomplished by a substrate processing apparatus including: a spin chuck adapted to hold a substrate having a substantially circular outer shape with the principal surface of the substrate set substantially horizontally and rotate the substrate with the center of the substrate as a rotation center; a processing liquid ejection nozzle adapted to eject a processing liquid to the circumferential edge part of the substrate rotated held by the spin chuck; and a cup adapted to be disposed in the external circumferential part of the substrate rotated held by the spin chuck and collect the processing liquid scattered from the substrate, and further including, above the surface of the substrate rotated held by the spin chuck, an anti-splash member that is disposed between a collision position where the processing liquid scattered from the substrate collides with the cup and the substrate and for preventing the processing liquid having collided with the cup from reaching the surface of the substrate rotated held by the spin chuck.

The substrate processing apparatus as described above is capable of suppressing the processing liquid from reaching a device pattern area on the surface of the substrate by the action of the anti-splash member, and properly processing the circumference part of the substrate.

In one preferred embodiment, the anti-splash member includes a cylindrical wall part extending downward from the end edge of the cup on the substrate side, and an opening part is formed in an area of the wall part facing the processing liquid ejection nozzle.

In one preferred embodiment, the opening part is formed from a position on an upper stream side in a rotational direction of the substrate than a position on an extension of a straight line connecting between the rotation center of the substrate and a position where the processing liquid ejection nozzle supplies the processing liquid to the substrate to a position on a lower stream side in the rotational direction of the substrate.

In one preferred embodiment, an end edge of the opening part on the upstream side in the rotational direction of the substrate is arranged on the upper stream side in the rotational direction of the substrate than the position on the extension of the straight line connecting between the rotation center of the substrate and the position where the processing liquid ejection nozzle supplies the processing liquid to the substrate, and an end edge of the opening part on the downstream side in the rotational direction of the substrate is arranged at a position separated on the lower stream side in the rotational direction of the substrate than the position on the extension of the straight line connecting between the rotation center of the substrate and the position where the processing liquid ejection nozzle supplies the processing liquid to the substrate.

In one preferred embodiment, the end edge of the opening part on the downstream side in the rotational direction of the substrate is arranged on a lower stream side in the rotational direction of the substrate than a position in a tangential direction of a circle formed by the outer circumference of the substrate at a position where the straight line connecting between the rotation center of the substrate and the position where the processing liquid ejection nozzle supplies the processing liquid to the substrate intersects with the circumferential edge of the substrate as viewed from the position where the processing liquid ejection nozzle supplies the processing liquid to the substrate.

In the substrate processing apparatus as described above, the action of the wall part can suppress the processing liquid from reaching the device pattern area on the surface of the substrate. At this time, the processing liquid scattered from the substrate reaches an area on the outer side of the wall part through the opening part, and therefore the collision between the processing liquid and the wall part can be prevented.

In one preferred embodiment, the substrate processing apparatus further includes a gas ejection nozzle adapted to eject gas to, at a position on an upper stream side in the rotational direction of the substrate than the position where the processing liquid ejection nozzle supplies the processing liquid to the substrate, eject gas to the circumferential edge part of the substrate rotated held by the spin chuck.

In one preferred embodiment, the end edge of the opening part in the rotational direction of the substrate is arranged on an upper stream side in the rotational direction of the substrate than a position on an extension of a straight line connecting between the rotation center of the substrate and a position where the gas ejection nozzle supplies the gas to the substrate.

In the substrate processing apparatus as described above, the gas from the gas ejection nozzle removes the processing liquid remaining in the circumferential edge part of the substrate, and therefore it can be suppressed that the processing liquid remaining in the circumferential edge part of the substrate and the processing liquid ejected from the processing liquid ejection nozzle collide with each other to cause splashes, and the splashed processing liquid reaches the device pattern area on the surface of the substrate.

In one preferred embodiment, multiple processing liquid ejection nozzles are disposed at the fore end of an arm swingable between a processing liquid supply position above the circumferential edge part of the substrate rotated held by the spin chuck and a withdrawn position separate from above the substrate rotated held by the spin chuck, and the multiple processing liquid ejection nozzles are selectively used.

The substrate processing apparatus as described above is capable of selectively supplying the multiple processing liquids to the circumferential edge part of the substrate to preferably process the circumferential edge part of the substrate.

In one preferred embodiment, the cup has a collision surface with which the processing liquid scattered from the substrate collides, and the collision surface is configured to be a tilted surface of which the upper part is close to the substrate rotated held by the spin chuck and the lower part is separate from the substrate rotated held by the spin chuck.

In the substrate processing apparatus as described above, the processing liquid having collided with the collision surface is mostly scattered downward, and therefore the amount of the processing liquid scattered toward the surface of the substrate can be decreased.

In one preferred embodiment, the lower end part of the wall part has a tilted surface of which the upper part is close to the substrate rotated held by the spin chuck and the lower part is separate from the substrate rotated held by the spin chuck.

The substrate processing apparatus as described above is capable of preferably perform liquid draining of the processing liquid attached to the wall part.

Other features and advantages of the invention will be apparent from the following detailed description of the embodiments of the invention.

### BRIEF DESCRIPTION OF THE DRAWINGS

For the purpose of illustrating the invention, there are shown in the drawings several forms which are presently preferred, it being understood, however, that the invention is not limited to the precise arrangement and instrumentalities shown.

FIG. 1 is a schematic front view schematically illustrating a substrate processing apparatus according to the present invention;

FIG. 2 is a schematic plan view illustrating the main part of the substrate processing apparatus according to the present invention;

FIG. 3 is a perspective view illustrating the main part of the substrate processing apparatus according to the present invention;

FIG. 4 is a schematic view illustrating a state where a processing liquid is supplied from a processing liquid ejection nozzle to the circumferential edge part of a semiconductor wafer;

FIG. 5 is a plan view illustrating the arrangement of an upper cup and the semiconductor wafer;

FIG. 6A is a partial vertical cross-sectional view illustrating the arrangement of the upper cup and the semiconductor wafer;

FIG. 6B is a partial vertical cross-sectional view illustrating the arrangement of the upper cup and the semiconductor wafer;

FIG. 7 is a plan view illustrating the arrangement relationship between a nozzle head and an opening part when the nozzle head is arranged at a position to supply nitrogen gas or a processing liquid to the vicinity of the circumferential edge part of the semiconductor wafer;

FIG. 8 is a schematic view of a first nitrogen gas ejection nozzle, processing liquid ejection nozzles, and the opening part formed in a wall part as viewed from the inner side of the upper cup when the nozzle head is arranged at the position to supply nitrogen gas or a processing liquid to the vicinity of the circumferential edge part of the semiconductor wafer;

FIG. 9 is an explanatory view illustrating the arrangement relationship between the wall part of the upper cup and the semiconductor wafer rotated held by suction by the spin chuck;

FIG. 10 is a schematic view of the first nitrogen gas ejection nozzle, the processing liquid ejection nozzles, and an opening part according to a variation and formed in the wall part as viewed from the inner side of the upper cup when the nozzle head is arranged at the position to supply nitrogen gas or a processing liquid to the vicinity of the circumferential edge part of the semiconductor wafer;

FIG. 11A is a partial vertical cross-sectional view illustrating the arrangement of an upper cup according to a second embodiment and the semiconductor wafer;

FIG. 11B is a partial vertical cross-sectional view illustrating the arrangement of the upper cup according to the second embodiment and the semiconductor wafer.

### DESCRIPTION OF THE PREFERRED EMBODIMENTS

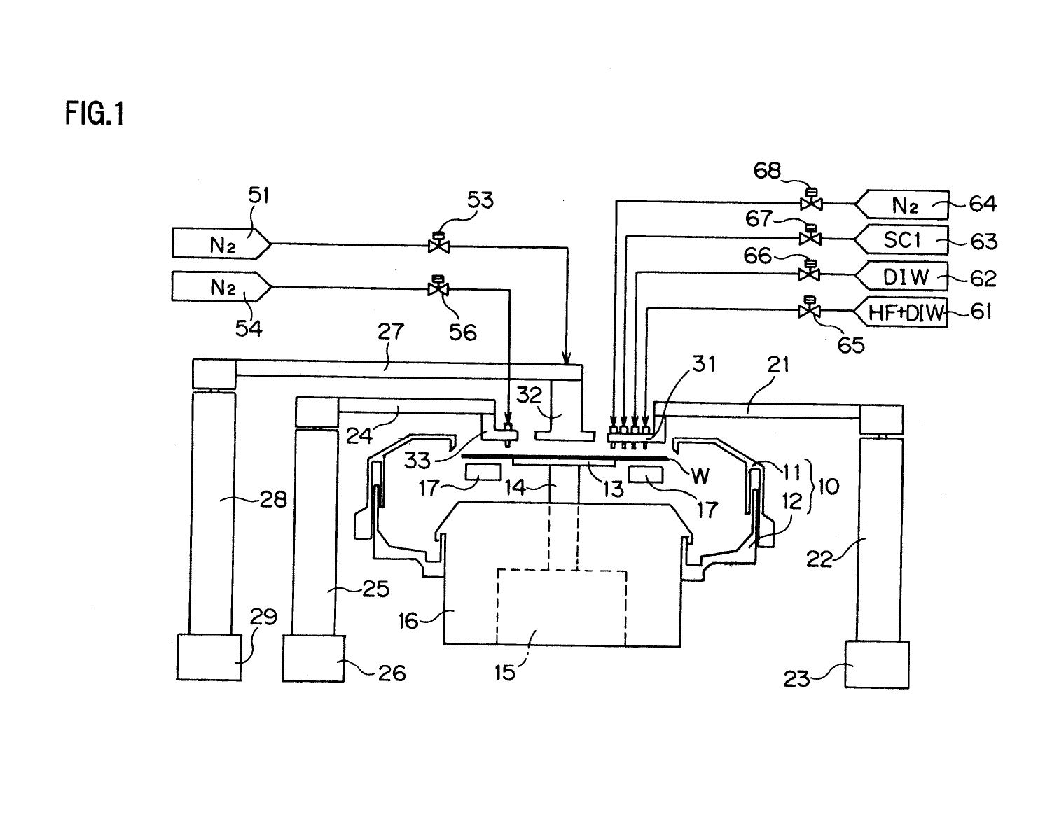

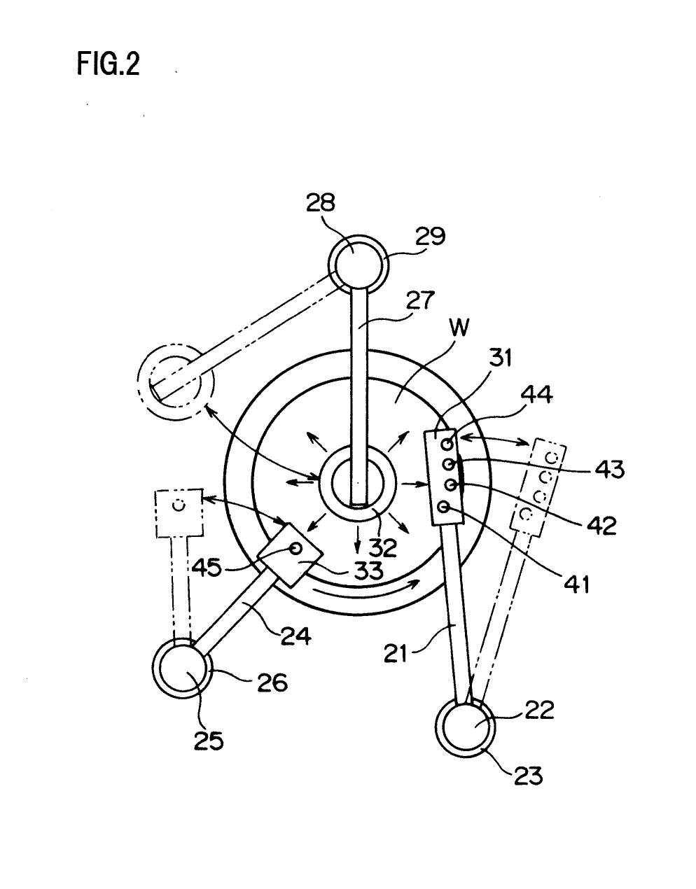

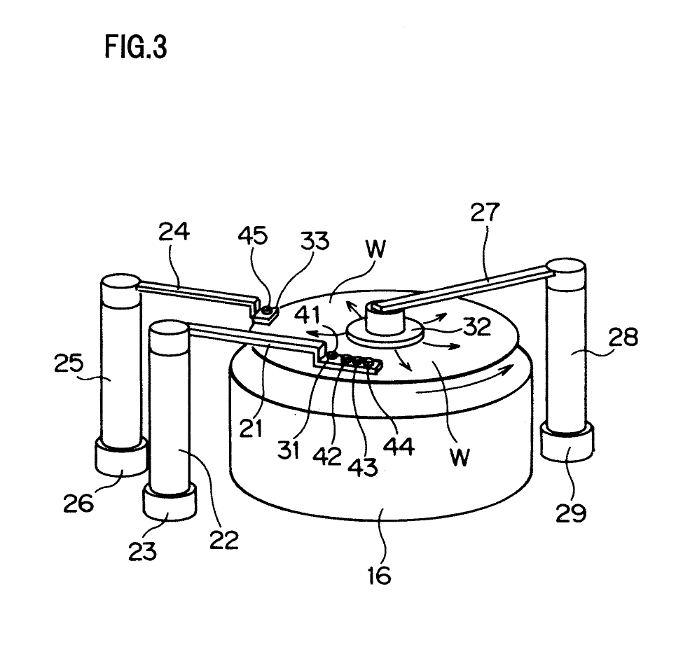

In the following, embodiments of the present invention will be described on the basis of the drawings. FIG. 1 is a schematic front view schematically illustrating a substrate processing apparatus according to the present invention. Also, FIG. 2 is a schematic plan view illustrating the main part of the substrate processing apparatus according to the present invention. Further, FIG. 3 is a perspective view illustrating the main part of the substrate processing apparatus according to the present invention.

The substrate processing apparatus is one adapted to process the circumferential edge part of a semiconductor wafer W as a substrate having a substantially circular outer shape. The substrate processing apparatus includes a spin chuck 13 that holds by suction the lower surface of the semiconductor wafer W with the principal surface of the semiconductor wafer W set substantially horizontally, and then rotates the semiconductor wafer W with the center of the semiconductor wafer W as a rotation center. The spin chuck 13 is connected via a shaft. 14 to a rotary drive mechanism 15 such as a motor disposed in a casing 16.

In the external circumferential part of the semiconductor wafer W rotated held by the spin chuck 13, a cup 10 for collecting a processing liquid scattered from the semiconductor wafer W is disposed. The cup 10 is configured to include an upper cup 11 and a lower cup 12. The upper cup 11 is capable of being moved up and down relative to the lower cup 12 by an unillustrated lifting mechanism. The upper cup 11 is such that when supplying a processing liquid to the semiconductor wafer W, the upper part thereof is arranged at a height position above the upper surface of the semiconductor wafer W held by suction by the spin chuck 13, and when loading in or out the semiconductor wafer W, the upper part thereof is arranged at a height position below the front surface of the semiconductor wafer W held by suction by the spin chuck 13.

In a position below the semiconductor wafer W held by suction by the spin chuck 13 and facing the circumferential edge part of the semiconductor wafer W, a heater 17 is disposed. The heater 17 is one for heating the circumferential edge part of the semiconductor wafer W in order to improve the efficiency of processing the semiconductor wafer W. When loading in or out the semiconductor wafer W, the heater is moved down by an unillustrated lifting mechanism to a position not to interfere with a loading mechanism.

The substrate processing apparatus has a nozzle head 31 including a first nitrogen ejection nozzle 41 and multiple processing liquid ejection nozzles 42, 43, and 44 (see FIGS. 2 and 3). The nozzle head 31 is supported by the fore end of an arm 21 swingable around a support part 22. The arm 21 is adapted to be swingable by driving of a motor 23 between a position to supply nitrogen gas or a processing liquid to the vicinity of the circumferential edge part of the semiconductor wafer W indicated by solid lines in FIG. 2 and a standby position indicated by virtual lines in FIG. 2.

The first nitrogen gas ejection nozzle 41 is connected to a supply source 64 of nitrogen gas as inert gas via an on-off valve 68 illustrated in FIG. 1. Also, the processing liquid ejection nozzle 42 is connected to a supply source 63 of SC1 as a processing liquid via an on-off valve 67 illustrated in FIG. 1. Further, the processing liquid ejection nozzle 43 is connected to a supply source 62 of deionized water (DIW) as a processing liquid via an on-off valve 66 illustrated in FIG. 1. Still further, the processing liquid ejection nozzle 44 is connected to a supply source 61 of a mixed liquid of HF and deionized water as a processing liquid via an on-off valve 65 illustrated in FIG. 1.

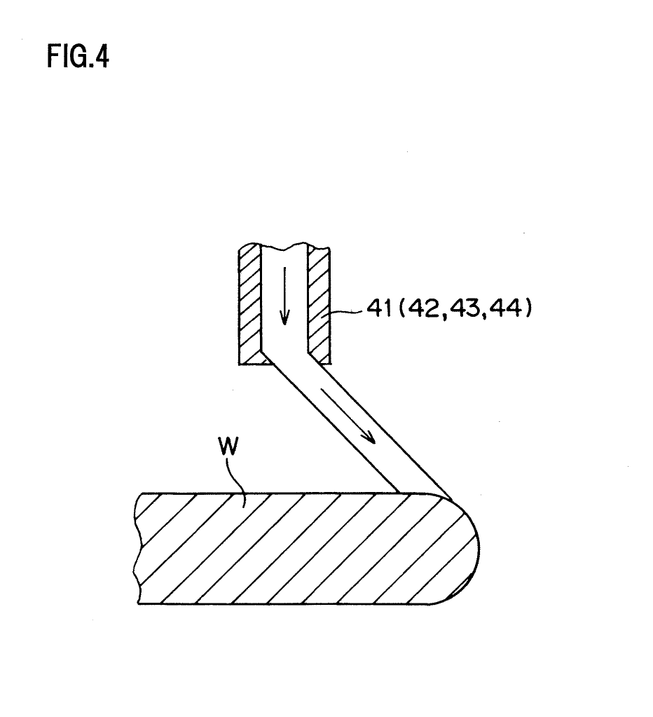

FIG. 4 is a schematic view illustrating a state where a processing liquid is supplied from a corresponding processing liquid ejection nozzle 42, 43, or 44 to the circumferential edge part of the semiconductor wafer W.

As illustrated in the view of FIG. 4, the lower end part of a processing liquid circulation path formed in a processing liquid ejection nozzle 42, 43, or 44 is configured to be tilted so as to face the circumferential edge part of the semiconductor wafer W rotated held by suction by the spin chuck 13. For this reason, even when vertically arranging the processing liquid ejection nozzles 42, 43, and 44 themselves, the processing liquids ejected from the processing liquid ejection nozzles 42, 43, and 44 can form flows in oblique directions toward the circumferential edge part of the semiconductor wafer W.

Referring to FIGS. 1 to 3 again, the substrate processing apparatus has a nozzle head 33 including a second nitrogen gas ejection nozzle 45 (see FIGS. 2 and 3). The nozzle head 33 is supported by the fore end of an arm 24 swingable around a support part 25. The arm 24 is adapted to be swingable by driving of a motor 26 between a position to supply nitrogen gas to the vicinity of the circumferential edge part of the semiconductor wafer W indicated by solid lines in FIG. 2 and a standby position indicated by virtual lines in FIG. 2. The second nitrogen gas ejection nozzle 45 is connected to a supply source 54 of nitrogen gas as inert gas via an on-off valve 56 illustrated in FIG. 1.

Also, the substrate processing apparatus includes a nitrogen gas ejection part 32. The nitrogen gas ejection part 32 is supported by the fore end of an arm 27 swingable around a support part 28. The arm 27 is adapted to be swingable by driving of a motor 29 between a position to supply nitrogen gas to the vicinity of the rotation center of the semiconductor wafer W indicated by solid lines in FIG. 2 and a standby position indicated by virtual lines in FIG. 2. The nitrogen gas ejection part 32 is configured to annex a shield plate to the lower end part of a cylindrical member, and also configured to form the flow of nitrogen gas from the vicinity of the rotation center of the semiconductor wafer W rotated held by suction by the spin chuck 13 to the circumferential edge part along the surface of the semiconductor wafer W. As illustrated in FIG. 1, the nitrogen gas ejection part 32 is connected to a supply source 51 of nitrogen gas as inert gas via an on-off valve 53.

The substrate processing apparatus is configured to etch and remove a film formed in the circumferential edge part by supplying the processing liquids from the processing liquid ejection nozzles 42, 43, and 44 to the circumferential edge part also referred to as a bevel on the outer side of a device pattern on the semiconductor wafer W. That is, the substrate processing apparatus rotates the semiconductor wafer W held by the spin chuck 13 with the center of the semiconductor wafer W as the rotation center. Then, the substrate processing apparatus arranges any of the processing liquid ejection nozzles 42, 43, and 44 above the circumferential edge part of the semiconductor wafer W and continuously supplies a processing liquid to the circumferential edge part of the semiconductor wafer W in rotation from the processing liquid ejection nozzle 42, 43, or 44. This allows the film formed in the circumferential edge part of the semiconductor wafer W to be etched and removed.

At this time, if after the processing liquid has been supplied to the circumferential edge part of the semiconductor wafer W from the processing liquid ejection nozzle 42, 43, or 44, in a state where the processing liquid supplied to the circumferential edge part of the semiconductor wafer W remains in a part of the circumferential edge part of the semiconductor wafer W, the part moves to a position facing the processing liquid ejection nozzle 42, 43, or 44 and the processing liquid is supplied, the processing liquid newly supplied from the processing liquid ejection muzzle 42, 43, or 44 hits the processing liquid remaining in the part of the circumferential edge part of the semiconductor wafer W to cause liquid splashes. Further, if droplets of the processing liquid caused by the liquid splashes are attached to a device pattern area on the surface of the semiconductor wafer W, there occurs a problem of causing a defect in a device pattern.

For this reason, the substrate processing apparatus employs a configuration adapted to, before supplying a processing liquid to the surface of the semiconductor wafer W from each of the processing liquid ejection nozzles 42, 43, and 44, remove the processing liquid remaining in the circumferential edge part of the semiconductor wafer W using nitrogen gas from the first nitrogen gas ejection nozzle 41 and the second nitrogen gas ejection nozzle 45.

At this time, in order to quickly remove the processing liquid remaining in the circumferential edge part of the semiconductor wafer W, it is only necessary to supply a large flow rate of nitrogen gas to the circumferential edge part of the semiconductor wafer W. However, if the large flow rate of nitrogen gas collides with the processing liquid remaining in the circumferential edge part of the semiconductor wafer W, the processing liquid splashes, and droplets of the processing liquid caused by the liquid splashes may be attached to the device pattern area on the surface of the semiconductor wafer W. On the other hand, if the flow rate of nitrogen gas to be supplied to the circumferential edge part of the semiconductor wafer W is set to be small, the processing liquid remaining in the circumferential part of the semiconductor wafer W cannot be sufficiently removed.

For this reason, the substrate processing apparatus employs a configuration adapted to completely remove a processing liquid remaining in the circumferential edge part of the semiconductor wafer W by supplying a small flow rate or low flow speed of nitrogen gas to the circumferential edge part of the semiconductor wafer W from the second nitrogen gas ejection nozzle 45 to remove the processing liquid from the circumferential part of the semiconductor wafer W to some extent, and then supplying a large flow rate or high flow speed of nitrogen gas to the circumferential edge part of the semiconductor wafer W from the first nitrogen gas ejection nozzle 41.

Note that when employing the configuration adapted to remove a processing liquid in the circumferential edge part of the semiconductor wafer W as described above, it is necessary to prevent the processing liquid from moving inward from the circumferential edge part of the semiconductor wafer W. To do this, it is necessary to supply nitrogen gas to a position closer to the center of the semiconductor wafer W than a position to eject a processing liquid from each of the processing liquid ejection nozzles 42, 43, and 44 to the circumferential part of the semiconductor wafer W.

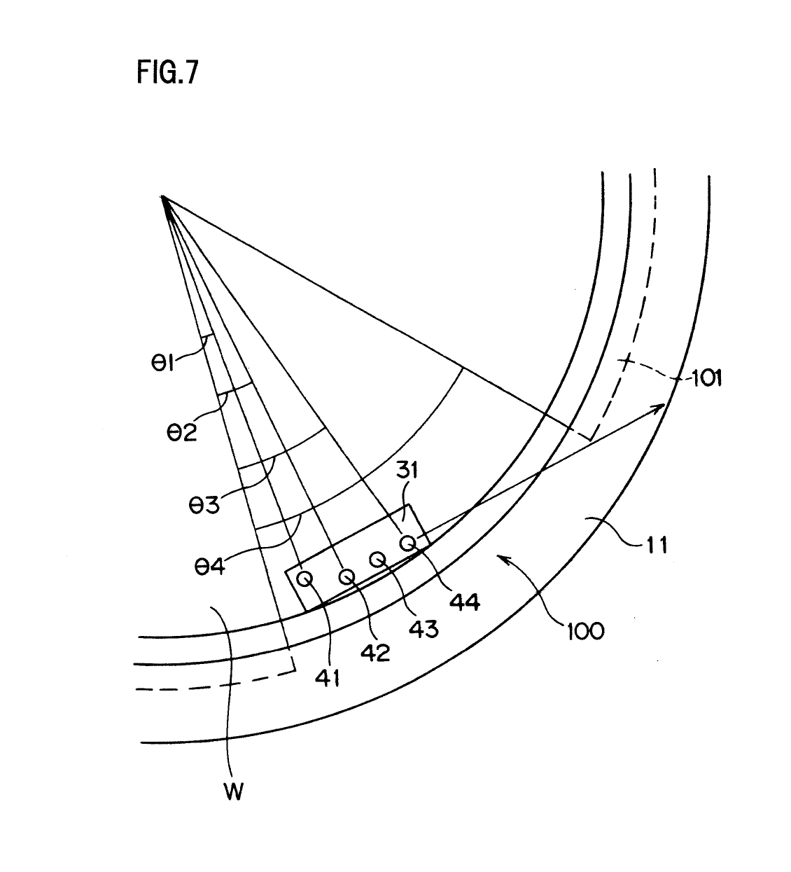

That is, as illustrated in FIG. 2 and below-described FIG. 7, the first nitrogen gas ejection nozzle 41 is arranged at a position closer to the rotation center of the semiconductor wafer W rotated held by suction by the spin chuck 13 than the processing liquid ejection nozzles 42, 43, and 44. The same holds true for the second nitrogen gas ejection nozzle 45.

Further, the substrate processing apparatus employs the configuration adapted to make the nitrogen gas ejection part 32 form the flow of nitrogen gas from the vicinity of the rotation center of the semiconductor wafer W rotated held by suction by the spin chuck 13 to the circumferential edge part along the surface of the semiconductor wafer W. For this reason, nitrogen gas ejected from the nitrogen gas ejection part 32 can further reduce the possibility of attachment of droplets of a processing liquid caused by liquid splashes to the device pattern area on the surface of the semiconductor wafer W.

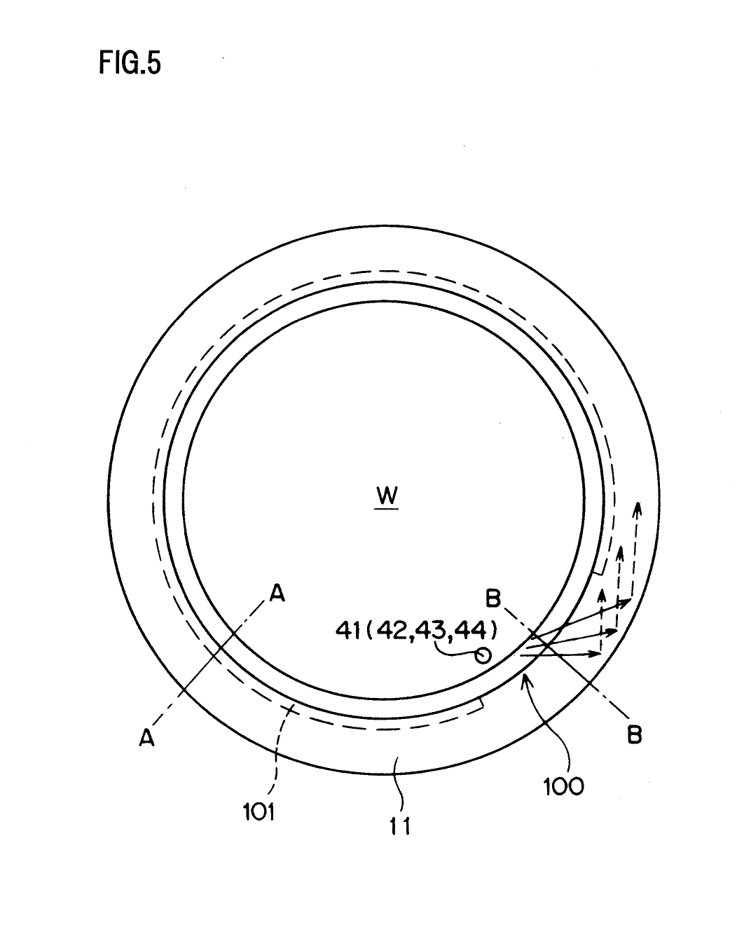

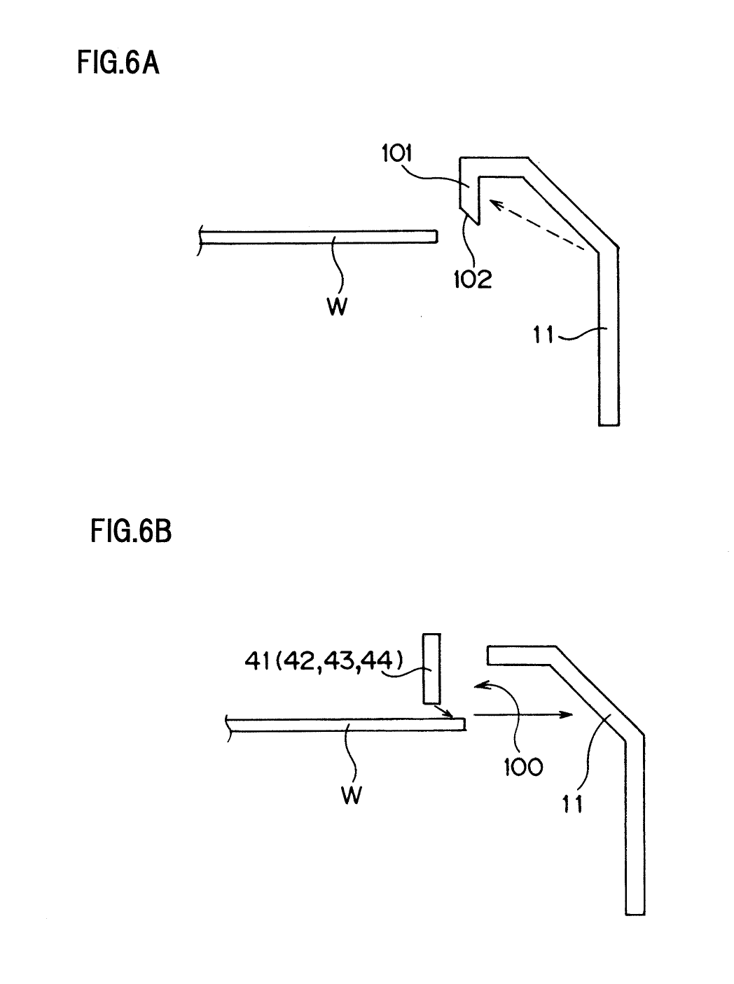

Next, a configuration of the upper cup 11 of the cup 10 as a feature of the present invention will be described. FIG. 5 is a plan view illustrating the arrangement of the upper cup 11 and the semiconductor wafer W. Also, FIGS. 6A and 6B are partial vertical cross-sectional views illustrating the arrangement of the upper cup 11 and the semiconductor wafer W. Note that FIG. 6A illustrates a vertical cross section along the line A-A of FIG. 5, and FIG. 6B illustrates a vertical cross section along the line B-B of FIG. 5.

As described above, the upper cup 11 constituting the cup 10 is one that is disposed in the external circumferential part of the semiconductor wafer W rotated held by the spin chuck 13 and for collecting a processing liquid scattered from the semiconductor wafer W. The upper cup 11 has a shape surrounding the semiconductor wafer W. The upper cup 11 includes a cylindrical wall part 101 extending downward from an end edge on the semiconductor wafer W side. The wall part 101 is not provided in part of an area of the upper cup 11 facing the outer circumferential part of the semiconductor wafer W, and the partial area is provided as an opening part 100. As described below, the partial area is an area near the position to eject a processing liquid from each of the processing liquid ejection nozzles 42, 43, and 44 to the semiconductor wafer W. In addition, as illustrated in FIG. 6A, the lower end part of the wall part 101 has a tilted surface 102 of which the upper part is close to the semiconductor wafer W rotated held by the spin chuck 13 and the lower part is separate from the semiconductor wafer W.

The rest of the upper cup 11 excluding the wall part 101 is configured to include: a horizontal part as an upper part facing in the horizontal direction; a tilted part connecting to the horizontal part; and a vertical part extending downward from the tilted part. In addition, the tilted part is configured to include a tilted surface of which the upper part is close to the semiconductor wafer W rotated held by the spin chuck 13 and the lower part is separate from the semiconductor wafer W. The tilted part includes a collision surface according to the present invention, with which a processing liquid scattered from the substrate collides.

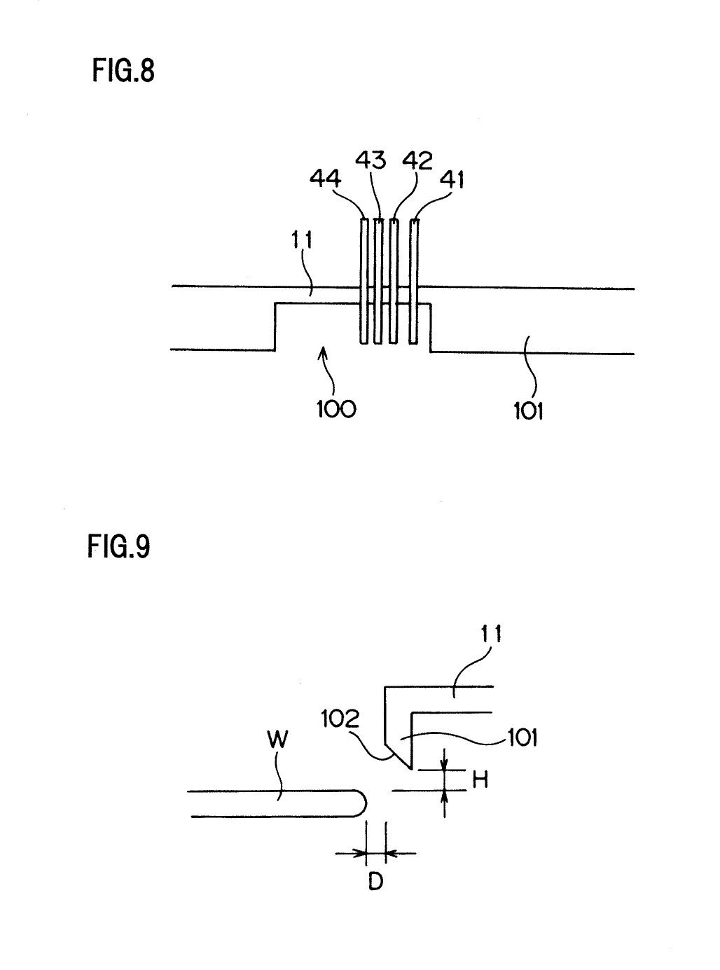

FIG. 7 is a plan view illustrating the arrangement relationship between the nozzle head 31 and the opening part 100 when the nozzle head 31 is arranged at a position to supply nitrogen gas or a processing liquid to the vicinity of the circumferential edge part of the semiconductor wafer W, which is indicated by the solid lines in FIG. 2. Also, FIG. 8 is a schematic view of the first nitrogen gas ejection nozzle 41, the processing liquid ejection nozzles 42, 43, and 44, and the opening part 100 formed in the wall part 101 as viewed from the inner side of the upper cup 11 at that time.

When ejecting a processing liquid from each of the processing liquid ejection nozzles 42, 43, and 44 toward the circumferential edge part of the semiconductor wafer W rotated held by suction by the spin chuck 13, the processing liquid supplied to the semiconductor wafer W is scattered outward of the semiconductor wafer W by centrifugal force. If in an area where the processing liquid is scattered, the wall part 101 of the upper cup 11 is arranged as illustrated in FIG. 6A, the processing liquid scattered from the semiconductor wafer W collides with the wall part 101. For this reason, as illustrated in FIGS. 6B and 8, in such an area, the opening part 101 is formed in the wall part 101. In addition, in an area other than such an area, as illustrated in FIG. 6A, the wall part 101 is arranged to prevent the processing liquid from colliding with the upper cup 11, being scattered, and reaching the surface of the semiconductor wafer W.

The opening part 100 has to be formed from a position on an upper stream side in the rotational direction of the semiconductor wafer W than positions on extensions of straight lines connecting between the rotation center of the semiconductor wafer W and the positions where the processing liquid ejection nozzles 42, 43, and 44 supply corresponding processing liquids to the semiconductor wafer W to a lower stream side in the rotational direction of the semiconductor wafer W. More specifically, the end edge of the opening part 100 on the upstream side in the rotational direction of the semiconductor wafer W has to be arranged on the upper stream side in the rotational direction of the semiconductor wafer W than the positions on the extensions of the straight lines connecting between the rotation center of the semiconductor wafer W and the positions where the processing liquid ejection nozzles 42, 43, and 44 supply corresponding processing liquids to the semiconductor wafer W. On the other hand, the end edge of the opening part 100 on the downstream side in the rotational direction of the semiconductor wafer W has to be arranged at a position separated on the lower stream side in the rotational direction of the semiconductor wafer W than the positions on the extensions of the straight lines connecting between the rotation center of the semiconductor wafer W and the position where the processing liquid ejection nozzles 42, 43, and 44 supply corresponding processing liquids to the semiconductor wafer W.

A processing liquid ejected from each of the processing liquid ejection nozzles 42, 43, and 44 to the circumferential edge part of the semiconductor wafer W is not only scattered outward by the centrifugal force of the semiconductor wafer W rotated held by suction by the spin chuck 13, but scattered in a tangential direction of a circle centered at the rotation center of the semiconductor wafer W. For this reason, as indicated by an arrow in FIG. 7, the end edge of the opening part 100 on the downstream side of the rotational direction of the semiconductor wafer W is preferably arranged on the lower stream side in the rotational direction of the semiconductor wafer W than positions in the tangential directions of the semiconductor wafer W at positions where the straight lines connecting between the rotation center of the semiconductor wafer W and the positions where the processing liquid ejection nozzles 42, 43, and 44 supply corresponding processing liquid to the semiconductor wafer W intersect with the circumferential edge of the semiconductor wafer W as viewed from the positions where the processing liquid ejection nozzles 42, 43, and 44 supply corresponding processing liquid to the semiconductor wafer W.

In addition, in the above-described embodiment, at a position on the upper stream side in the rotational direction of the semiconductor wafer W than the positions where the processing liquid ejection nozzles 42, 43, and 44 supply corresponding processing liquid to the semiconductor wafer W, the substrate processing apparatus further includes the first nitrogen gas ejection nozzle 41 adapted to eject the gas to the circumferential edge part of the semiconductor wafer W. In doing so, the action of nitrogen gas ejected from the first nitrogen gas ejection nozzle 41 allows a processing liquid first ejected to the circumferential edge part of the semiconductor wafer W from any of the processing liquid ejection nozzles 42, 43, and 44 and remaining on the semiconductor wafer W to be removed and scattered outward of the semiconductor wafer W. Therefore, in the present embodiment, the end edge of the opening part 100 on the upstream side in the rotational direction of the semiconductor wafer W is preferably arranged on an upper stream side in the rotational direction of the semiconductor wafer W than a position on an extension of a straight line connecting between the rotation center of the semiconductor wafer W and a position where the first nitrogen gas ejection nozzle supplies nitrogen gas to the semiconductor wafer W.

Note that the action of nitrogen gas ejected from the above-described second nitrogen gas ejection nozzle 45 also allows a processing liquid first ejected to the circumferential edge part of the semiconductor wafer W from any of the processing liquid ejection nozzles 42, 43, and 44 and remaining on the semiconductor wafer W to be removed and scattered outward of the semiconductor wafer W. However, as described above, since the substrate processing apparatus employs the configuration adapted to supply a small flow rate or low speed of nitrogen gas from the second nitrogen gas ejection nozzle 45 as compared with nitrogen gas ejected from the first nitrogen gas ejection nozzle 41, it is not necessary to form an opening part in an area facing the second nitrogen gas ejection nozzle 45. That is, a processing liquid scattered outward of the semiconductor wafer W is mostly scattered to the upper cup 11 through the opening part 100.

For example, given that the diameter of the semiconductor wafer W is 300 mm, and the number of revolutions of the semiconductor wafer W is 1300 rpm, as illustrated in FIG. 7, it is preferable that with respect to the rotation center of the semiconductor wafer W, the angle θ1 formed between the end edge of the opening part 100 on the upstream side in the rotational direction of the semiconductor wafer W and the first nitrogen gas ejection nozzle 41 is approximately 2 degrees; the angle θ2 formed between the end edge of the opening part 100 on the upstream side in the rotational direction of the semiconductor wafer W and the processing liquid ejection nozzle 42 is approximately 4 degrees; the angle θ3 formed between the end edge of the opening part 100 on the upstream side in the rotational direction of the semiconductor wafer W and the processing liquid ejection nozzle 44 is approximately 20 degrees; and the angle θ4 formed between the end edge of the opening part 100 on the upstream side in the rotational direction of the semiconductor wafer W and the end edge on the downstream side is approximately 45 degrees.

FIG. 9 is an explanatory view illustrating the arrangement relationship between the wall part 101 of the upper cup 11 and the semiconductor wafer W rotated held by suction by the spin chuck 13.

The distance H between the lower end part of the wall part 101 of the upper cup 11 and the surface of the semiconductor wafer W rotated held by suction by the spin chuck 13 is preferably approximately a few mm. When decreasing the distance H, a processing liquid scattered from the semiconductor wafer W may collide with the wall part 101. On the other hand, when increasing the distance H, a processing liquid having collided with the upper cup 11 may reach the surface of the semiconductor wafer W. Also, the distance D between the inner surface of the wall part 101 of the upper cup 11 and the end part of the semiconductor wafer W rotated held by suction by the spin chuck is preferably small to the extent that when the upper cup 11 is moved up, the upper cup 11 and the semiconductor wafer W do not interfere with each other.

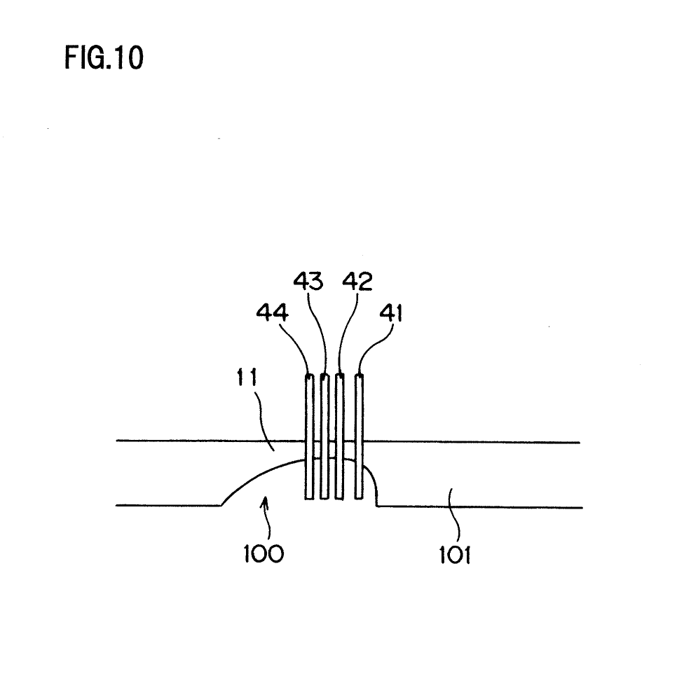

Note that in the above-described embodiment, the opening part 100 is of a rectangular shape as illustrated in FIG. 8. However, the opening part 100 according to the present invention is not limited to such a shape. FIG. 10 is a schematic view of the first nitrogen gas ejection nozzle 41, the processing liquid ejection nozzles 42, 43, and 44, and an opening part 100 according to a variation and formed in the wall part 101 as viewed from the inner side of the upper cup 11 when the nozzle head 31 is arranged in the position to supply nitrogen gas or a processing liquid to the vicinity of the circumferential edge part of the semiconductor wafer W.

As illustrated in the view of FIG. 10, the upper end of the opening part 100 may be of a curved shape. In this case, the upper end of the opening part 100 is preferably made higher in position on the upstream side in the rotational direction of the semiconductor wafer W, where a more amount of processing liquid is scattered, and lower in position on the downstream side of the rotational direction.

When the substrate processing apparatus having the configuration as described above performs an etching process on the circumferential edge part of the semiconductor wafer W, the semiconductor wafer W is held by suction by the spin chuck 13, and then the nozzle head 31, nozzle head 33, and nitrogen gas ejection part 32 are arranged in the positions indicated by the solid lines in FIG. 2. Subsequently, the upper cup 11 is moved up to a position illustrated in FIGS. 1, 6A, and 6B.

In this state, the semiconductor wafer W is rotated together with the spin chuck 13. Then, SC1 is first supplied to the circumferential edge part of the semiconductor wafer W from the processing liquid ejection nozzle 42. SC1 supplied to the semiconductor wafer W is scattered from the end edge of the semiconductor wafer W, passes through the opening 100 formed in the wall part 101 of the upper cup 11, and then collides with the tilted collision surface of the upper cup 11. SC1 having collided with the collision surface is mostly scattered downward, and therefore the amount of SC1 scattered toward the surface of the semiconductor wafer W can be decreased.

Also, part of the scattered SC1 floats while joining the flow of air circulating in the same direction as the rotational direction of the semiconductor wafer W. However, as illustrated in FIG. 6A, above the surface of the semiconductor wafer W, the part of SC1 is collected by the wall part 101 disposed between a collision position where SC1 scattered from the semiconductor wafer W collides with the collision surface of the upper cup 11 and the semiconductor wafer W. Then, the collected SC1 drops from the lower end part of the wall part 101. Since the lower end part of the wall part 101 has the tilted surface 102 of which the upper part is close to the semiconductor wafer W and the lower part is separate from the semiconductor wafer W, liquid draining of SC1 attached to the wall part 101 can be preferably performed.

SC1 remaining on the end edge of the semiconductor wafer W is removed to some extent by a small flow rate or low flow speed of nitrogen gas supplied from the second nitrogen gas ejection nozzle 45 to the circumferential edge part of the semiconductor wafer W, and then completely removed by a large flow rate or high flow speed of nitrogen gas supplied from the first nitrogen gas ejection nozzle 41 to the circumferential edge part of the semiconductor wafer W. In doing so, liquid splashes caused by further supplying SC1 in a state where SC1 supplied from the processing liquid ejection nozzle 42 remains in the circumferential edge part of the semiconductor wafer W can be prevented from occurring.

After performing the SC1-based process as described above, similar processes are also performed using the other processing liquids. That is, continuously, deionized water is supplied from the processing liquid ejection nozzle 43 to the circumferential edge part of the semiconductor wafer W to perform a cleaning process, then the mixed liquid of HF and deionized water is supplied from the processing liquid ejection nozzle 44 to the circumferential edge part of the semiconductor wafer W to perform an etching process, and further deionized water is again supplied from the processing liquid ejection nozzle 43 to the circumferential edge part of the semiconductor wafer W to perform a cleaning process. In the case of the processes using those processing liquids as well as in the case of SC1, the action of the wall part 101 can prevent each of the processing liquids from reaching the device pattern area on the surface of the semiconductor wafer W. At this time, a processing liquid scattered from the semiconductor wafer W reaches an area on the outer side of the wall part 101 through the opening part 100, and therefore the collision between the processing liquid and the wall part 101 can be effectively prevented.

Note that during those processes, nitrogen gas is constantly supplied from the nitrogen gas ejection part 32, and therefore the flow of nitrogen gas from the vicinity of the rotation center of the semiconductor wafer W rotated held by suction by the spin chuck 13 to the circumferential edge part along the surface of the semiconductor wafer W is formed. This allows the possibility of attachment of droplets of a processing liquid to the device pattern area on the surface of the semiconductor wafer W to be further reduced.

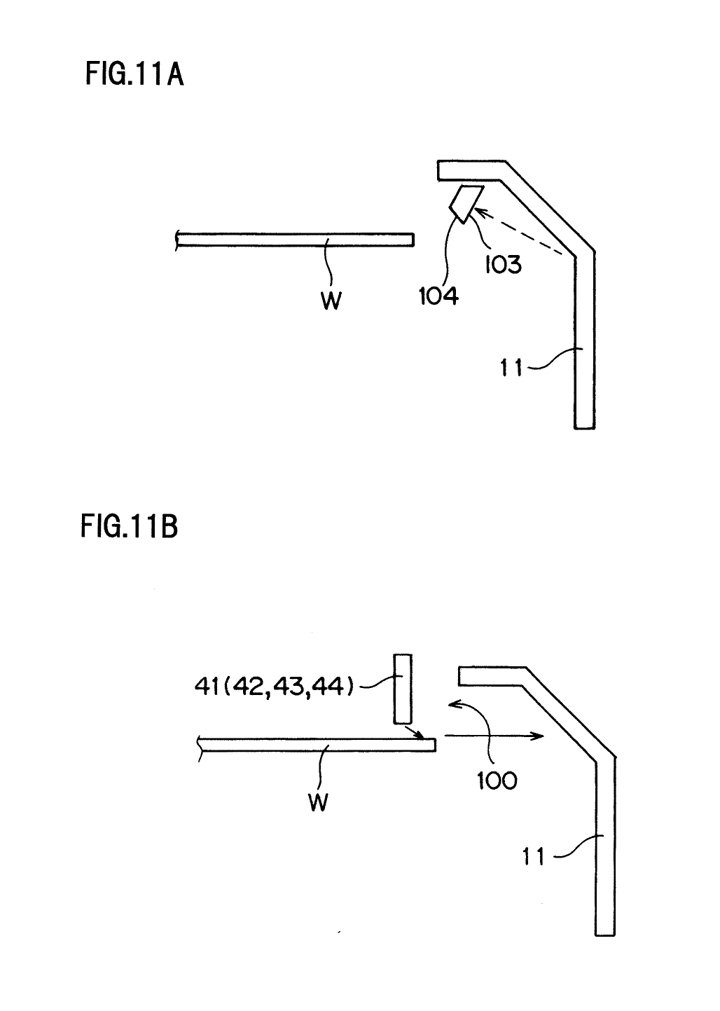

FIGS. 11A and 11B are partial vertical cross-sectional views illustrating the arrangement of an upper cup 11 according to a second embodiment of the present invention and the semiconductor wafer W.

In the above-described first embodiment, the wall part 101 that is disposed between the collision position where a processing liquid scattered from the semiconductor wafer W substrate collides with the upper cup 11 and the semiconductor wafer W above the surface of the semiconductor wafer W rotated held by the spin chuck 13 and of a cylindrical shape extending downward from the end edge of the upper cup 11 on the semiconductor wafer W side is used as anti-splash member for preventing the processing liquid having collided with the upper cup 11 from reaching the surface of the semiconductor wafer W. On the other hand, in the second embodiment, an anti-splash member 103 arranged on the outer side of the semiconductor wafer W and below the upper end of the upper cup 11 is used.

As illustrated in FIG. 11A, the anti-splash member 103 is disposed in an area corresponding to the area of the wall part 101 other than the opening part 100 in the first embodiment. In the area facing the opening part 100 of the wall part 101 in the first embodiment, the anti-splash member 103 is not disposed as illustrated in FIG. 11B. In addition, the lower end part of the anti-splash member 103 has a tilted surface 104 of which the upper part is close to the semiconductor wafer W rotated held by the spin chuck 13 and the lower part is separate from the semiconductor wafer W as with the lower end part of the wall part 101 according to the first embodiment.

In the case of using the anti-splash member 103 as well as in the case of using the wall part 101, the action of the anti-splash member 103 can suppress each processing liquid from reaching the device pattern area on the surface of the semiconductor wafer W. At this time, the processing liquid scattered from the semiconductor wafer W reaches the outer area through the area where the anti-splash member 103 is not present, and therefore the collision between the processing liquid and the anti-splash member 103 can be effectively prevented.

This invention may be embodied in other specific forms without departing from the spirit or essential attributes thereof and, accordingly, reference should be made to the appended claims, rather than to the foregoing specification, as indicating the scope of the invention.

This application claims priority benefit under 35 U.S.C. Section 119 of Japanese Patent Application No. 2016-175353 filed in the Japanese Patent Office on Sep. 8, 2016, the entire disclosure of which is incorporated herein by reference.

What is claimed is:

1. A substrate processing apparatus comprising:
a spin chuck adapted to hold a substrate having a substantially circular outer shape with a principal surface of the substrate set substantially horizontally and rotate the substrate with a center of the substrate as a rotation center;
a processing liquid ejection nozzle adapted to eject a processing liquid to a circumferential edge part of the substrate rotated held by the spin chuck; and
a cup adapted to be disposed in an external circumferential part of the substrate rotated held by the spin chuck and collect the processing liquid scattered from the substrate, the substrate processing apparatus further comprising
above the surface of the substrate rotated held by the spin chuck, an anti-splash member that is disposed between a collision position where the processing liquid scattered from the substrate collides with the cup and the substrate and for preventing the processing liquid having collided with the cup from reaching the surface of the substrate rotated held by the spin chuck.

2. The substrate processing apparatus according to claim 1, wherein
the anti-splash member comprises a cylindrical wall part extending downward from an end edge of the cup on a substrate side, and
an opening part is formed in an area of the wall part, the area facing the processing liquid ejection nozzle.

3. The substrate processing apparatus according to claim 2, wherein
the opening part is formed from a position on an upper stream side in a rotational direction of the substrate than a position on an extension of a straight line connecting between the rotation center of the substrate and a position where the processing liquid ejection nozzle supplies the processing liquid to the substrate to a position on a lower stream side in the rotational direction of the substrate.

4. The substrate processing apparatus according to claim 3, wherein
an end edge of the opening part on an upstream side in the rotational direction of the substrate is arranged on the upper stream side in the rotational direction of the substrate than the position on the extension of the straight line connecting between the rotation center of the substrate and the position where the processing liquid ejection nozzle supplies the processing liquid to the substrate, and
an end edge of the opening part on a downstream side in the rotational direction of the substrate is arranged at a position separated on the lower stream side in the rotational direction of the substrate than the position on the extension of the straight line connecting between the rotation center of the substrate and the position where the processing liquid ejection nozzle supplies the processing liquid to the substrate.

5. The substrate processing apparatus according to claim 4, wherein
the end edge of the opening part on the downstream side in the rotational direction of the substrate is arranged on a lower stream side in the rotational direction of the substrate than a position in a tangential direction of a circle formed by an outer circumference of the substrate at a position where the straight line connecting between the rotation center of the substrate and the position where the processing liquid ejection nozzle supplies the processing liquid to the substrate intersects with a circumferential edge of the substrate as viewed from the position where the processing liquid ejection nozzle supplies the processing liquid to the substrate.

6. The substrate processing apparatus according to claim 2, further comprising
a gas ejection nozzle adapted to eject gas to, at a position on an upper stream side in the rotational direction of the substrate than the position where the processing liquid ejection nozzle supplies the processing liquid to the substrate, eject gas to the circumferential edge part of the substrate rotated held by the spin chuck.

7. The substrate processing apparatus according to claim 6, wherein
the end edge of the opening part in the rotational direction of the substrate is arranged on an upper stream side in the rotational direction of the substrate than a position on an extension of a straight line connecting between the rotation center of the substrate and a position where the gas ejection nozzle supplies the gas to the substrate.

8. The substrate processing apparatus according to claim 2, wherein
multiple processing liquid ejection nozzles are disposed at a fore end of an arm swingable between a processing liquid supply position above the circumferential edge part of the substrate rotated held by the spin chuck and a withdrawn position separate from above the substrate rotated held by the spin chuck, and the multiple processing liquid ejection nozzles are selectively used.

9. The substrate processing apparatus according to claim 2, wherein
the cup comprises a collision surface with which the processing liquid scattered from the substrate collides, and
the collision surface is configured to be a tilted surface of which an upper part is close to the substrate rotated held by the spin chuck and a lower part is separate from the substrate rotated held by the spin chuck.

10. The substrate processing apparatus according to claim 2, wherein
a lower end part of the wall part comprises a tilted surface of which an upper part is close to the substrate rotated held by the spin chuck and a lower part is separate from the substrate rotated held by the spin chuck.
